(19) United States
(12) Patent Application Publication
(10) Pub. No.: US 2024/0312772 A1
(43) Pub. Date: Sep. 19, 2024

(54) APPARATUS AND METHOD FOR CURRENT SENSING USING EMBEDDED ELECTRODES

(71) Applicant: MKS Instruments, Inc., Andover, MA (US)

(72) Inventors: Chiu-Ying Tai, Chelmsford, MA (US); Michael Harris, Hudson, MA (US); Ilya Pokidov, Winchester, MA (US); Joseph Desjardins, Bedford, NH (US); Gordon Hill, Arlington, MA (US)

(21) Appl. No.: 18/122,509

(22) Filed: Mar. 16, 2023

(51) Int. Cl. H01J 37/32

(52) U.S. Cl. CPC H01J 37/32935; H01J 37/32357; H01J 2237/24564

(57) ABSTRACT

An in-situ current sensing apparatus for a plasma processing system has one or more sections defining a plasma channel, the plasma processing system configured to form a plasma in the plasma channel using a process gas. The in-situ current sensing apparatus includes an assembly including an electrically conductive housing coupled to a dielectric coating layer, wherein a surface of the dielectric coating layer is configured to physically contact at least one of the process gas or the plasma in the plasma channel. The in-situ current sensing apparatus also includes a current probe, inductively or electrically connected to the assembly, for sensing a capacitively-coupled current within the assembly caused by the formation of plasma in the plasma channel. The in-situ current-sensing apparatus further includes at least one dielectric break for electrically isolating the assembly from the one or more sections. The assembly may include an electrode embedded within the housing.

### BACKGROUND

### Technical Field

The present invention relates to plasma generation and processing equipment, and more particularly to in-situ current sensing for plasma processing systems.

### Background

Plasma discharges can be used to excite gases to produce activated gases containing ions, free radicals, atoms, and molecules. Activated gases are used for numerous industrial and scientific applications, including processing solid materials such as semiconductor wafers, powders, and other gases. The parameters of the plasma and the conditions of the exposure of the plasma to the material being processed vary widely depending on the application.

Plasma discharges can be generated in a manner such that both the charged species constituting the plasma and the neutral species, which can be activated by the plasma, are in intimate contact with the material being processed. Alternatively, the plasma discharge can be generated remotely from the material being processed, so that relatively few of the charged species contact the material being processed, while the reactive neutral species can still contact it. Such a plasma discharge is commonly termed a remote plasma discharge. Depending on its construction, positioning relative to the material being processed, and operating conditions (e.g., gas species, pressure, flow rate, and power coupled into the plasma), a plasma source can have characteristics of either or both of these two general types.

A remote plasma source (RPS) generates plasma and provides reactive radicals to other devices downstream. The plasma-facing surface inside a RPS is usually covered by dielectric material, such as a ceramic coating, to maintain plasma stability and to minimize metal contamination. After exposure to plasma, it is unavoidable that the plasma facing surface inside the RPS applicator, i.e., the dielectric coating, wears down. The decay of the coating may eventually lead to a plasma “punch through” situation and cause serious particle and performance issues. In addition, plasma stability varies during operation of the RPS due to multiple reasons. These changes in plasma stability may lead to larger problems downstream (such as causing wafer defects) if they are not detected in time.

### SUMMARY

The deficiencies of the prior art are overcome by providing an apparatus that is an in-situ tool to monitor plasma stability and coating thickness degradation via current sensing. The apparatus described herein also provides a solution for the radical recombination issue downstream of the RPS.

In accordance with one embodiment of the present invention, an in-situ current sensing apparatus for a plasma processing system has one or more sections defining a plasma channel, the plasma processing system configured to form a plasma in the plasma channel using a process gas. The in-situ current sensing apparatus includes an assembly including an electrically conductive housing coupled to a dielectric coating layer, wherein a surface of the dielectric coating layer is configured to physically contact at least one of the process gas or the plasma in the plasma channel. The in-situ current sensing apparatus also includes a current probe, inductively or electrically connected to the assembly, for sensing a capacitively-coupled current within the assembly caused by the formation of plasma in the plasma channel. The in-situ current-sensing apparatus further includes at least one dielectric break for electrically isolating the assembly from the one or more sections.

Alternatively or in addition, the electrically conductive housing includes one or more electrically conductive flanges coupled to the dielectric coating layer. The current probe may be connected to one of the one or more flanges.

Alternatively or in addition, the assembly further includes an electrode embedded within the housing between an insulation layer and a dielectric barrier layer. The dielectric barrier layer is adapted to contact the plasma in the plasma channel. The current probe optionally may be inductively or electrically coupled to the electrode.

Also alternatively or in addition, the current probe is inductively or electrically coupled to the housing. The assembly may be configured to be switched between electrically coupled to ground and electrically floating.

Further alternatively or in addition, the in-situ current sensing apparatus is further configured to calculate a thickness of the dielectric coating layer based on the sensed current from the current probe. The controller may also be further configured to detect a change in composition of the process gas based on the sensed current. The controller may further be configured to determine stability of the plasma in the plasma channel.

Alternatively or in addition, the one or more sections of the plasma processing system include at least one input section, a plurality of mid-block sections, and at least one output section, the assembly being one of the mid-block sections of the plasma processing system.

Also alternatively or in addition, the at least one dielectric break includes a first dielectric break located at an interface between the one mid-block section and the at least one input section. The at least one dielectric break also includes a second dielectric break located at an interface between the one mid-block section and the at least one output section. The first and second dielectric breaks are configured to electrically isolate the one mid-block section from the input and output section.

In accordance with another embodiment of the present invention, a method for performing in-situ current sensing in a plasma processing apparatus having one or more sections defining a plasma channel, includes coupling a current-sensing device to the plasma processing apparatus, wherein the current-sensing device includes an assembly comprising an electrically conductive housing coupled to a dielectric coating layer and a current probe inductively or electrically connected to the assembly. The method also includes contacting, by a surface of the dielectric coating layer of the current-sensing device, at least one of a process gas or a plasma in the plasma channel. The method further includes electrically isolating the current-sensing device from the one or more sections of the plasma processing apparatus. The method includes electrically grounding the current-sensing device. The method also includes sensing, by the current probe, a capacitive current in the assembly.

Alternatively or in addition, the assembly of the current-sensing device further includes (i) at least one flange defined by the housing, the at least one flange coupled to the dielectric coating layer; and (ii) an electrode embedded in the housing between an insulating layer and a dielectric barrier layer, the dielectric barrier layer adapted to contact at least one of the plasma gas or the plasma in the plasma channel.

Alternatively or in addition, the method further includes using the embedded electrode to ignite the plasma in the plasma channel in a plasma ignition process, wherein the embedded electrode is electrically floating during the plasma ignition process.

Also alternatively or in addition, sensing the capacitive current by the current probe is performed after the plasma ignition process by electrically grounding one of the embedded electrode and the conductive housing. The current probe may be one of inductively coupled to a grounding path and electrically connected between ground and one of the embedded electrode and the conductive housing to sense the capacitive current. The current probe may also be one of inductively coupled to a grounding path and electrically connected between ground and the at least one flange of the assembly to sense the capacitive current.

Further alternatively or in addition, the method includes detecting erosion in a thickness of the dielectric coating layer using the sensed current. Alternatively or in addition, the method includes detecting a change in composition of the process gas using the sensed current. Also alternatively or in addition, the method includes detecting a degree of stability of the plasma in the plasma channel using the sensed current.

Alternatively or in addition, the current-sensing device is integrally formed with the plasma processing apparatus such that the current-sensing device is one of the one or more sections.

### BRIEF DESCRIPTION OF THE DRAWINGS

The description below refers to the accompanying drawings, of which:

FIG. 1 is an illustration of an in-situ current sensing apparatus, as used in a plasma processing system, in accordance with an embodiment of the present invention;

FIG. 2 is an illustration of an in-situ current sensing apparatus in accordance with an embodiment of the present invention;

FIG. 3 is an illustration of a plasma processing system and an in-situ current sensing apparatus in accordance with an embodiment of the present invention;

FIG. 4 is an illustration of an in-situ current sensing apparatus, as used in a plasma processing system, in accordance with an embodiment of the present invention;

FIG. 5 is an illustration of an in-situ current sensing apparatus in accordance with an embodiment of the present invention;

FIG. 6 is an illustration of an in-situ current sensing apparatus, as used in a plasma processing system, in accordance with an embodiment of the present invention;

FIG. 7 is an illustration of an in-situ current sensing apparatus in accordance with an embodiment of the present invention;

FIG. 8 shows current sensing results obtained from an in-situ current sensing apparatus in accordance with an embodiment of the present invention;

FIG. 9 shows current sensing results obtained from an in-situ current sensing apparatus in accordance with an embodiment of the present invention;

FIG. 10 shows current sensing results obtained from an in-situ current sensing apparatus in accordance with an embodiment of the present invention; and

FIG. 11 is a flowchart of a method for performing in-situ current sensing in accordance with an embodiment of the present invention.

### DETAILED DESCRIPTION OF ILLUSTRATIVE EMBODIMENTS

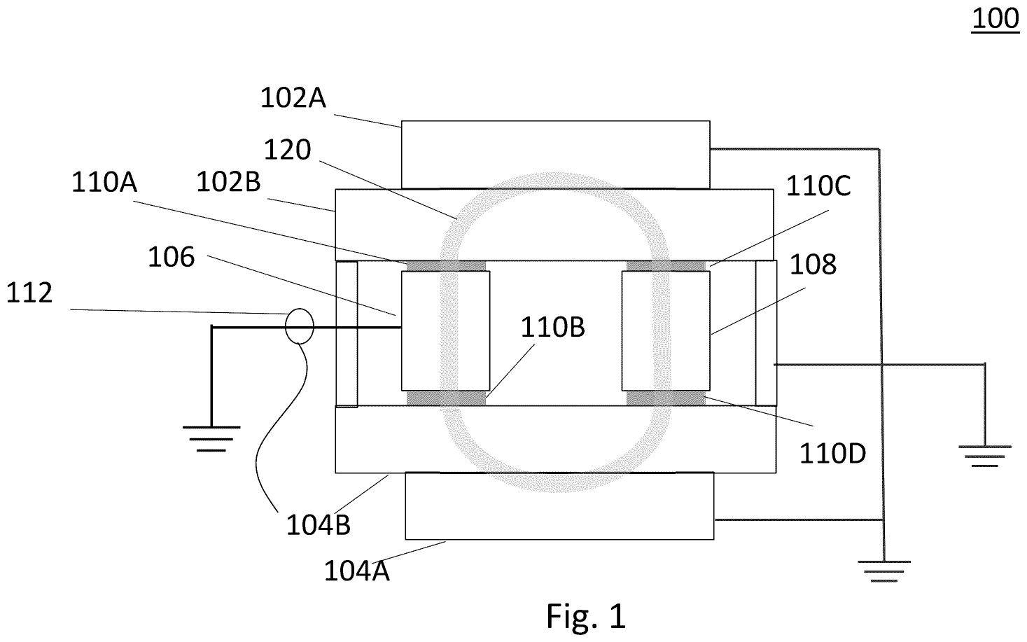

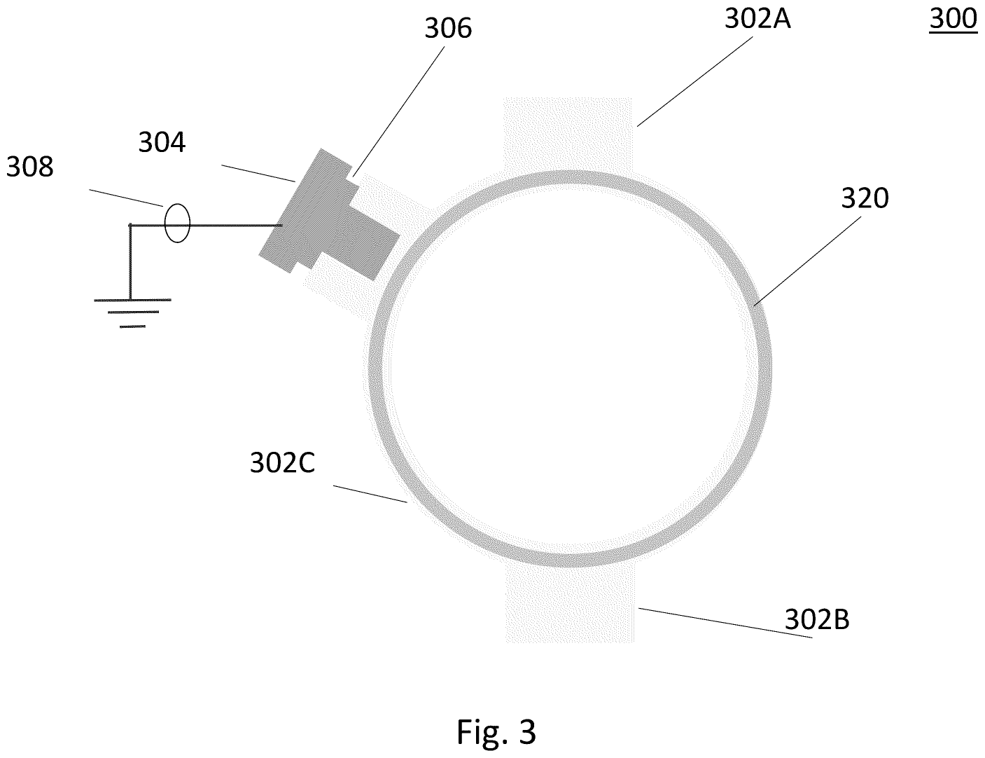

FIG. 1 is an illustration of an in-situ current sensing apparatus, as used in a plasma processing system, in accordance with an embodiment of the present invention. In-situ current sensing apparatus 100 is shown disposed in an exemplary plasma processing system. The plasma processing system has one or more sections that define a plasma channel. For example, the plasma processing system shown has sections 102A, 102B, 104A, 104B, 106, and 108. Sections 102A and 102B are input sections. Sections 106 and 108 are mid-block sections, and sections 104A and 104B are output sections. The sections 102A, 102B, 104A, 104B, 106, and 108 define a plasma channel 120. Illustratively, the plasma channel 120 is a toroidal plasma channel. However, and as shown below in FIG. 3, different configurations of plasma processing systems are expressly contemplated. The plasma processing system is configured to form plasma in the plasma channel using a process gas. The plasma processing system may form plasma in any way known to a skilled person.

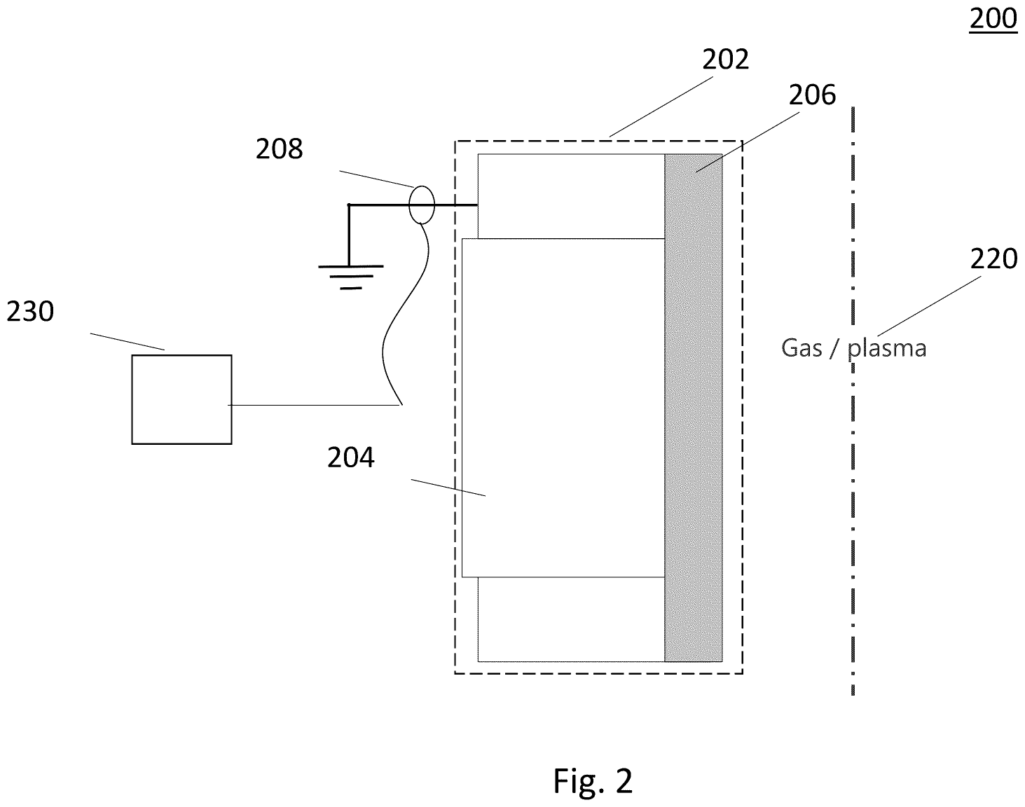

The in-situ current sensing apparatus 100 includes an assembly which is illustratively integrated into mid-block section 106 and shown in more detail below with reference to FIG. 2. The current sensing apparatus 100 also includes a current probe 112. The current probe 112 is inductively or electrically connected to the assembly and is configured to sense a capacitively coupled current within the assembly that is caused by the formation of plasma in the plasma channel 120. To this end, the assembly is also electrically coupled to ground. In other embodiments, described in more detail below, the assembly is not coupled to ground but electrically floating. The current sensing apparatus 100 also includes at least one dielectric break. The exemplary apparatus shown in FIG. 1 includes four dielectric breaks 110A, 110B, 110C, and 110D. Dielectric break 110A electrically isolates the assembly, as integrated into mid-block section 106, from the input section 102B. Dielectric break 110B electrically isolates the assembly, as integrated into mid-block section 106, from the output section 104B. Dielectric break 110C electrically isolates mid-block section 108 from input section 102B. Dielectric break 110D electrically isolates mid-block section 108 from output section 104B. By way of example, sections 102A, 102B, 104A, and 104B are electrically grounded. Sections 106 and 108, the mid-block sections, are electrically floating. While no current-sensing apparatus is shown in FIG. 1 that includes an assembly integrated into mid-block section 108, it is expressly contemplated that a current-sensing apparatus may be connected to mid-block section 108, either in addition to or alternatively to the current-sensing apparatus 100.

FIG. 2 is an illustration of an in-situ current sensing apparatus in accordance with an embodiment of the present invention. In-situ current sensing apparatus 200 may, for example, be integrated into a mid-block section of a plasma processing system, such as mid-block section 106 shown in FIG. 1. The current sensing apparatus 200 includes an assembly 202 that has an electrically conductive housing 204. The housing may, for example, be manufactured from aluminum. It is expressly noted that the housing may also be manufactured from a different suitable electrically conductive material, such as titanium, or from a suitable and electrically conductive combination of materials. The electrically conductive housing 204 is coupled to a dielectric coating layer 206. The dielectric coating layer 206 may, for example, be manufactured from anodized aluminum, or it may be manufactured from any other suitable material or combination of materials known to the skilled person. A surface of the coating layer 206 is arranged and configured to physically contact the contents 220 of the plasma channel. The contents 220 of the plasma channel may be a process gas, plasma, or a combination thereof. The current-sensing apparatus 200 also includes a current probe 208 that is inductively or electrically coupled to the assembly 202. In the embodiment shown in FIG. 2, the current probe 208 is inductively or electrically coupled to the conductive housing 204. As described above with reference to current probe 112, the current probe 208 is configured to sense a capacitively coupled current within the assembly 202, the current being caused by the formation of plasma in the plasma channel.

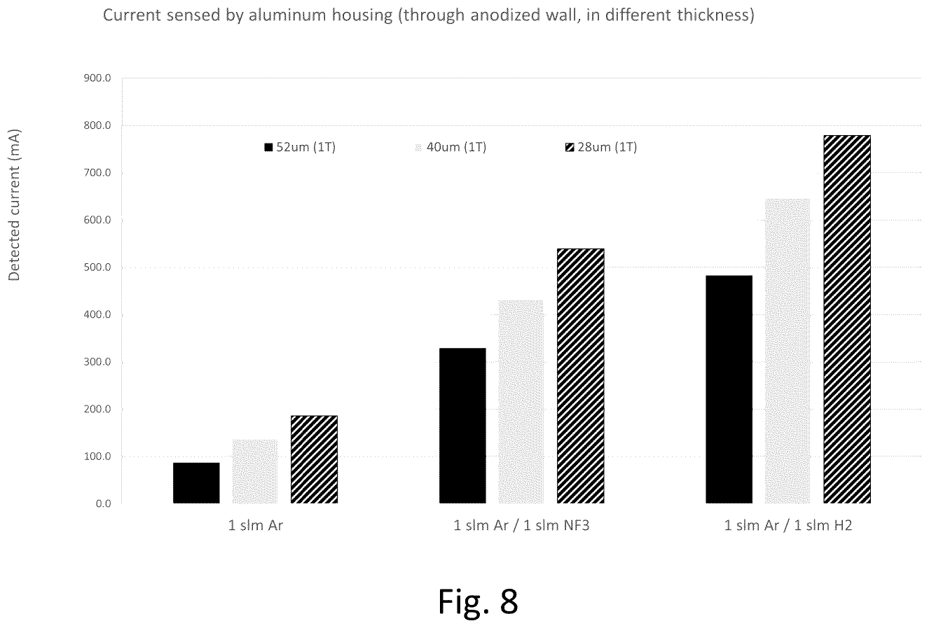

In one embodiment, the conductive housing is coupled to ground, and the current probe 208 may be configured to be inductively coupled to the grounding path or electrically connected between ground and the conductive housing. In this configuration, the current probe 208 senses the capacitively coupled current within the assembly that is caused by the formation of plasma in the plasma channel. To this end, the in-situ current sensing apparatus 200 may include a controller 230 that is electrically coupled to the current probe 208. The controller 230 receives the sensed current from the current probe. The controller 230 may be any device or combination of devices known to the skilled person that is capable of receiving and processing the sensed current. Exemplarily, the controller 230 may be a processor coupled to a memory, a computer system, a microcontroller, or any other signal processing device. The controller 230 is configured to calculate a thickness of the dielectric coating layer 206 based on the sensed current. Plasma is an electrically quasineutral medium that contains unbound positive and negative particles, neutral atoms, and molecules. Plasma ions are attracted to a grounded or biased surface area, and an electric current is then detected. Since the current probe 208 is inductively or electrically coupled to the conductive housing 204, the conductive housing 204 is also coupled to ground. Only the dielectric coating layer 206 provides an insulation between the plasma in the plasma channel and the grounded conductive housing 204. Ions from the plasma capacitively cause a current in the ground path through the dielectric coating layer 206 and are sensed by the current probe 208. The capacitively coupled current has a linear relationship with the thickness of the dielectric coating layer 206. In other words, the thinner the dielectric coating layer 206 is, the higher the capacitively coupled current sensed by the current probe 208. The sensed current therefore allows to indirectly measure the thickness of the dielectric coating layer 206. The controller 230 may be configured to calculate the thickness of the dielectric coating layer 206 based on a pre-programmed relationship between sensed current and thickness, based on selected parameters, based on one or more previous measurements of the sensed current in relation with known thicknesses of the dielectric coating layer, or a combination thereof. As can be seen below in FIG. 8, the sensed current also depends on gas flow and the composition of process gases and/or plasma in the plasma channel.

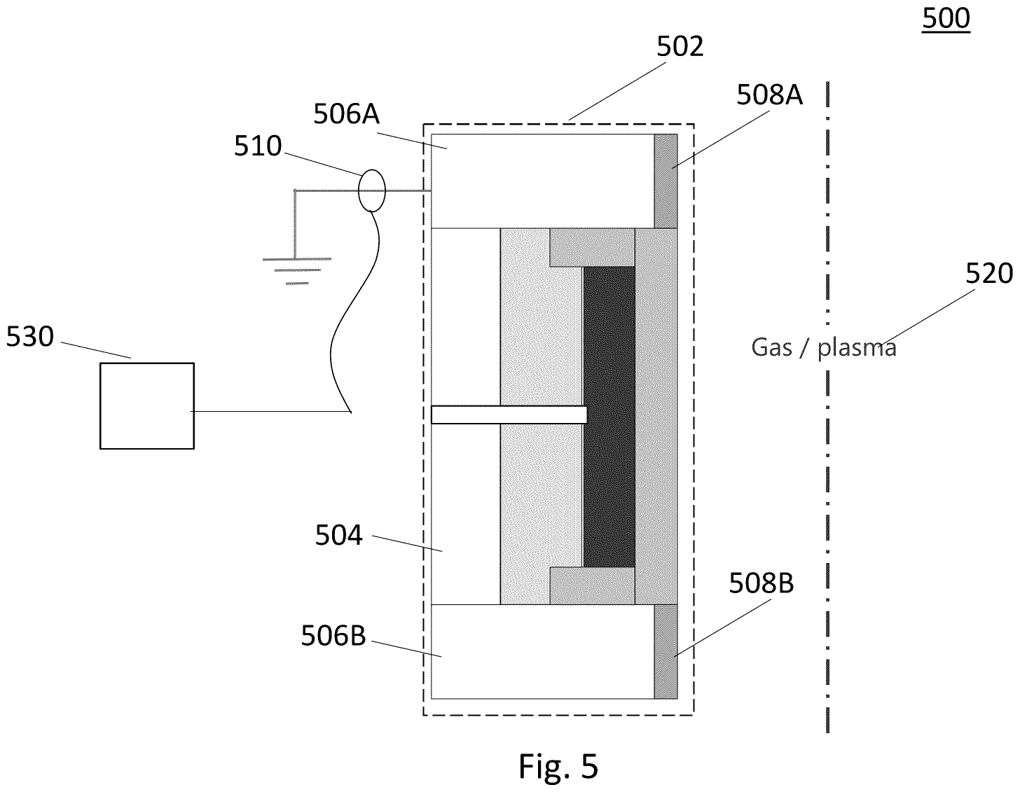

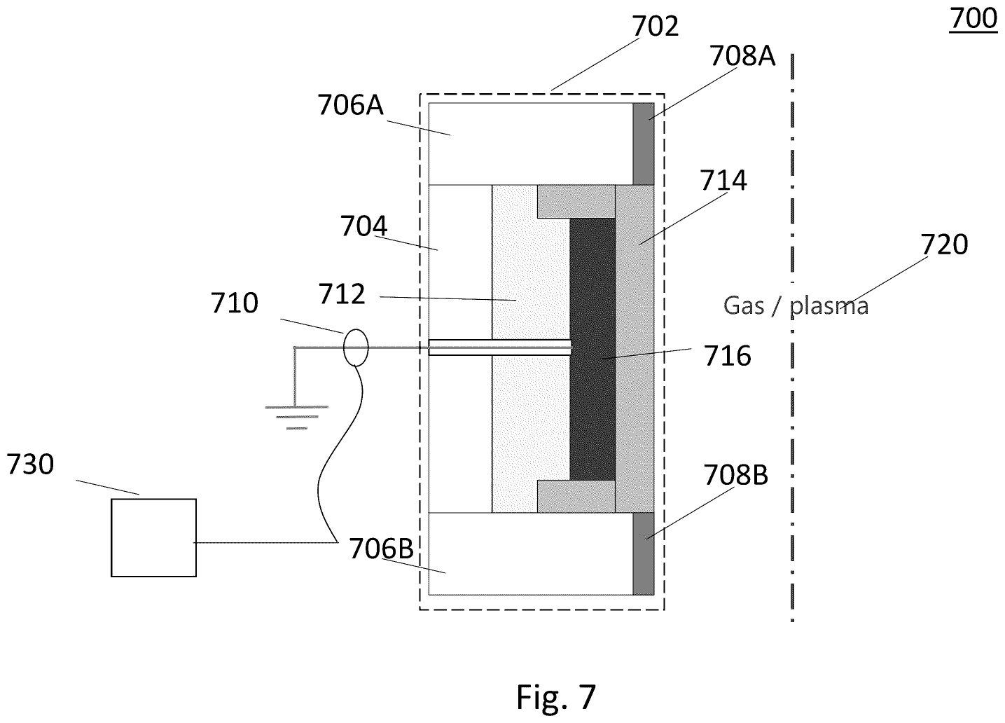

FIG. 3 is an illustration of a plasma processing system and an in-situ current sensing apparatus in accordance with an embodiment of the present invention. In-situ current sensing apparatus 300 is shown in an exemplary plasma processing system that includes sections 302A, 302B, and 302C. The sections 302A, 302B, and 302C define a plasma channel 320 where plasma is formed using a process gas. Similar to the embodiment above, the current sensing apparatus 300 includes an assembly 304 that includes an electrically conductive housing coupled to a dielectric coating layer (not shown). A surface of the dielectric coating layer is configured to physically contact the contents of the plasma channel 320, which may be plasma, a process gas, or combinations thereof. The current sensing apparatus 300 also includes a current probe 308 that is electrically coupled to the assembly 304. The current probe 308 is configured to sense a capacitively coupled current within the assembly 304, the current being caused by the formation of plasma in the plasma channel 320. The current sensing apparatus also includes a dielectric break 306 that electrically isolates the assembly 304 from section 302C. The current sensing apparatus 300 is located outside of the main plasma loop, and only its dielectric coating layer is in contact with plasma. The current sensing apparatus 300 may be configured similar to what is described above with reference to FIG. 2, or it may be configured similar to what is described below with reference to FIGS. 5 and 7.

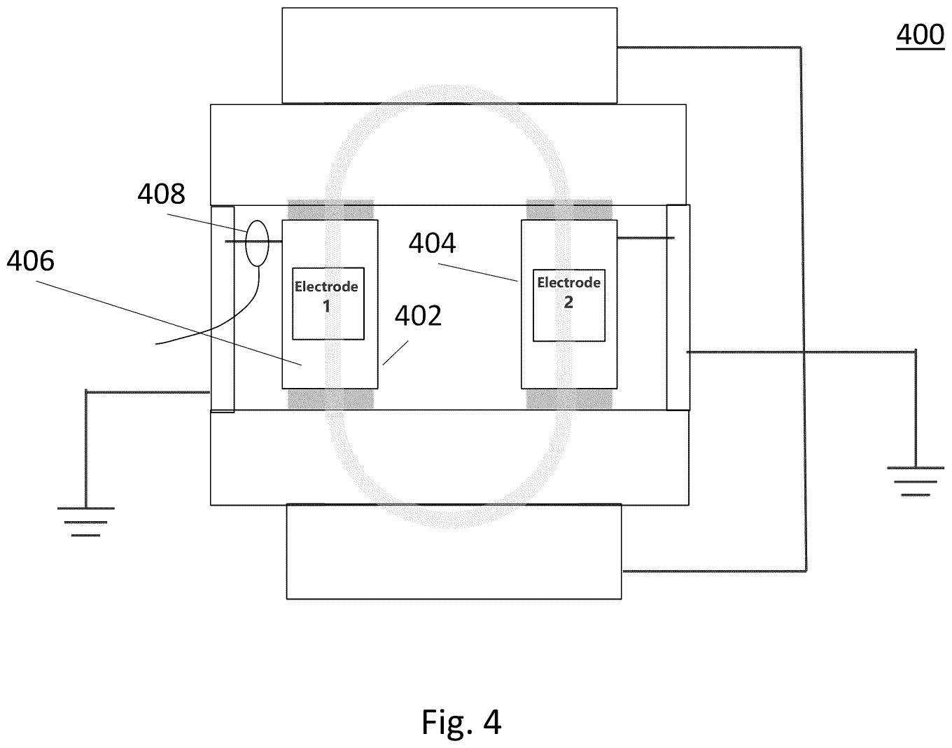

FIG. 4 is an illustration of an in-situ current sensing apparatus, as used in a plasma processing system, in accordance with an embodiment of the present invention. In-situ current sensing apparatus 400 is shown in a plasma processing system similar to the one described above with reference to FIG. 1. In the embodiment shown in FIG. 4, the plasma processing system includes two mid-block sections 402 and 404. In-situ current sensing apparatus 400 is shown to be associated with mid-block section 402, but it expressly contemplated that mid-block 404 may also have an associated current sensing apparatus in addition to or alternatively to current-sensing apparatus 400. The current-sensing apparatus 400 includes a current probe 408 that is inductively or electrically coupled to housing 406 as described in detail below.

FIG. 5 is an illustration of an in-situ current sensing apparatus in accordance with an embodiment of the present invention. Illustratively, in-situ current sensing apparatus 500 is disposed in a mid-block section of a plasma processing system, such as mid-block section 402 shown in FIG. 4. However, it is expressly contemplated that current-sensing apparatus 500 is disposed in or associated with other parts of a plasma processing system. For example, current-sensing apparatus 500 may be located outside of the main plasma loop, such as apparatus 300 in FIG. 3.

The current sensing apparatus 500 includes an assembly 502 that has an electrically conductive housing 504. The housing may, for example, be manufactured from aluminum. It is expressly noted that the housing may also be manufactured from a different suitable electrically conductive material, such as titanium, or from a suitable and electrically conductive combination of materials. The electrically conductive housing 504 includes electrically conductive flanges 506A and 506B. The flanges 506A and 506B may be manufactured from aluminum or from another suitable conductive material or combination of materials. Flanges 506A and 506B may be manufactured from the same material or from different materials. In addition, while two flanges are shown here, it is expressly contemplated that the housing includes only one flange or more than two flanges. Electrically conductive flange 506A is coupled to a dielectric coating layer 508A, and electrically conductive flange 506B is coupled to dielectric coating layer 508B. The dielectric coating layers 508A and 508B may, for example, be manufactured from anodized aluminum, or they may be manufactured from any other suitable material or combination of materials known to the skilled person. It is also expressly noted that the dielectric coating layer 508A may be manufactured from a different material than dielectric coating layer 508B. A surface of each one of the coating layers 508A and 508B is arranged and configured to physically contact the contents 520 of the plasma channel. The contents 520 of the plasma channel may be a process gas, plasma, or a combination thereof. The current-sensing apparatus 500 also includes a current probe 510 that is inductively or electrically coupled to flange 506A. Alternatively, the current probe 510 may be inductively or electrically coupled to flange 506B. Similar to current probes 112 and 208, the current probe 510 is configured to sense a capacitively coupled current within the assembly 502, the current being caused by the formation of plasma in the plasma channel. The current probe 510 is coupled to a controller 530. Similar to what is described in detail above with reference to FIG. 2, the controller 530 is configured to calculate the thickness of dielectric coating layer 508A from the sensed current. If the current probe 510 is coupled to flange 506B, the controller 530 calculates the thickness of dielectric coating layer 508B.

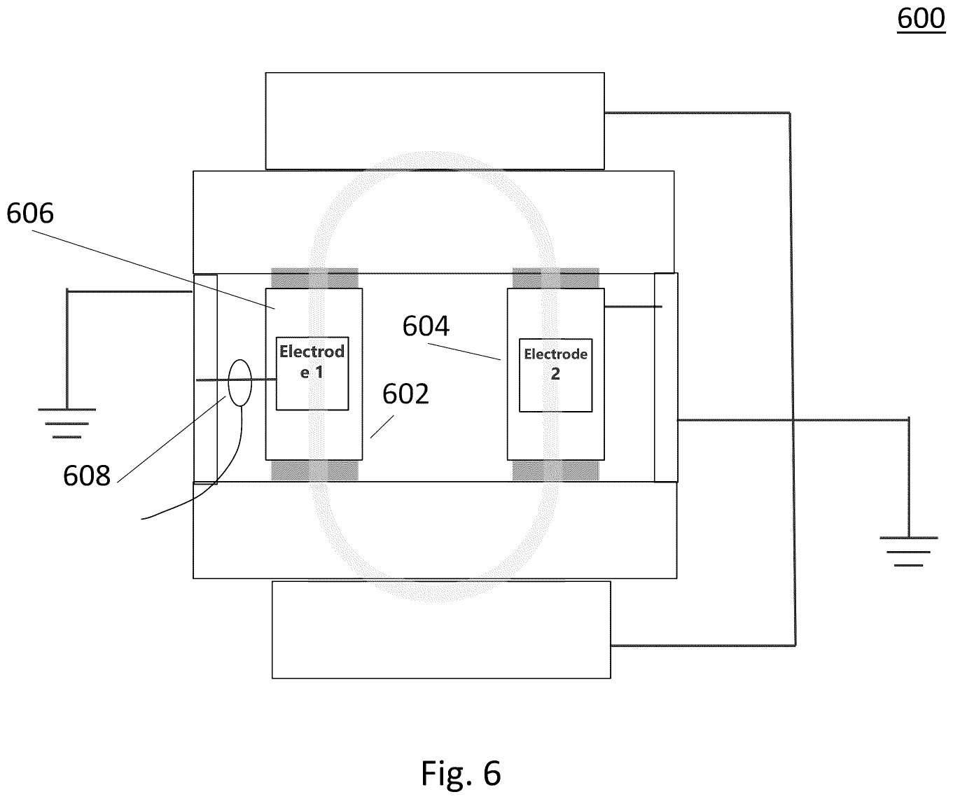

FIG. 6 is an illustration of an in-situ current sensing apparatus, as used in a plasma processing system, in accordance with an embodiment of the present invention. In-situ current sensing apparatus 600 is shown in a plasma processing system similar to the one described above with reference to FIG. 1. In the embodiment shown in FIG. 6, the plasma processing system includes two mid-block sections 602 and 604. In-situ current sensing apparatus 600 is associated with mid-block section 602, but it expressly contemplated that mid-block 604 may also have an associated current sensing apparatus in addition to or alternatively to current-sensing apparatus 600. The current-sensing apparatus 600 includes a current probe 608 that is inductively or electrically coupled to an electrode 606 as described in detail below.

FIG. 7 is an illustration of an in-situ current sensing apparatus in accordance with an embodiment of the present invention. Illustratively, in-situ current sensing apparatus 700 is disposed in or associated with a mid-block section of a plasma processing system, such as mid-block section 602 shown in FIG. 6. However, it is expressly contemplated that current-sensing apparatus 700 is disposed in or associated with other parts of a plasma processing system. For example, current-sensing apparatus 700 may be located outside of the main plasma loop, such as apparatus 300 in FIG. 3.

The current sensing apparatus 700 includes an assembly 702 that has an electrically conductive housing 704. The housing may, for example, be manufactured from aluminum. It is expressly noted that the housing may also be manufactured from a different suitable electrically conductive material, such as titanium, or from a suitable and electrically conductive combination of materials. The electrically conductive housing 704 includes electrically conductive flanges 706A and 706B. The flanges 706A and 706B may be manufactured from aluminum or from another suitable conductive material or combination of materials. Flanges 706A and 706B may be manufactured from the same material or from different materials. In addition, while two flanges are shown here, it is expressly contemplated that the housing includes only one flange or more than two flanges. Electrically conductive flange 706A is coupled to a dielectric coating layer 708A, and electrically conductive flange 706B is coupled to dielectric coating layer 708B. The dielectric coating layers 708A and 708B may, for example, be manufactured from anodized aluminum, or they may be manufactured from any other suitable material or combination of materials known to the skilled person. It is also expressly noted that the dielectric coating layer 708A may be manufactured from a different material than dielectric coating layer 708B. A surface of each one of the coating layers 708A and 708B is arranged and configured to physically contact the contents 720 of the plasma channel. The contents 720 of the plasma channel may be a process gas, plasma, or a combination thereof.

The assembly 702 also includes an electrode 716 that is embedded in the housing 704. Electrode 716 may be manufactured from copper, silver, gold, combinations thereof, or another suitable metal known to the skilled person. The electrode 716 may also have a different geometry from what is shown. The electrode 716 is embedded between an insulation layer 712 and a dielectric barrier layer 714. The insulation layer 712 may be manufactured from any suitable material that is electrically insulating. The dielectric barrier layer 714 may be manufactured from aluminum oxide, aluminum nitride, ytrria, from a high purity ceramic material, or from combinations thereof. It may also be manufactured from any other suitable material or combination of materials known to the skilled person. The dielectric barrier layer 714 is configured to physically contact the plasma, the process gas, and/or combinations thereof in the plasma channel.

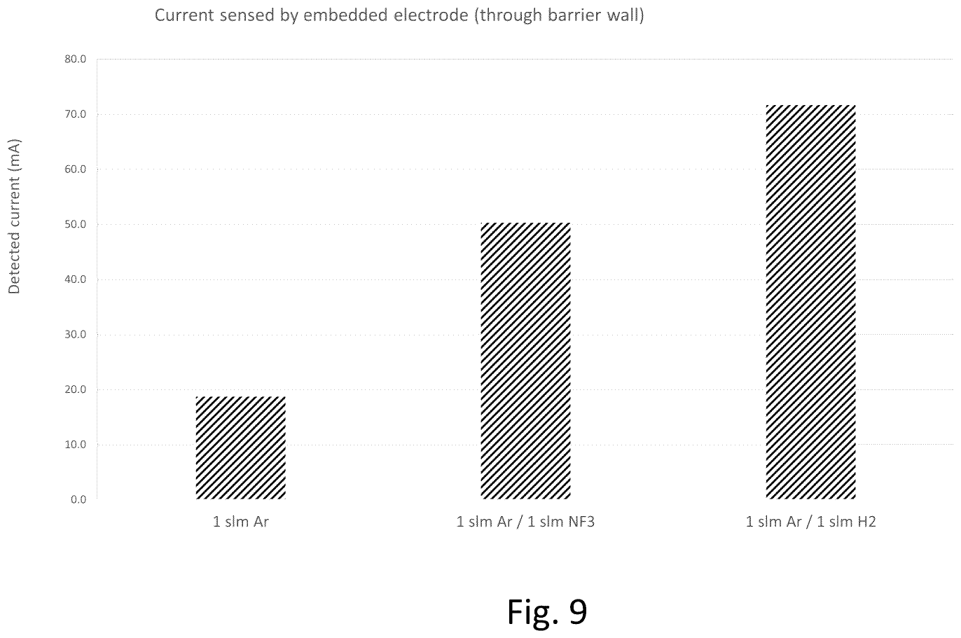

The current-sensing apparatus 700 further includes a current probe 710 that is inductively or electrically coupled to the electrode 716. Similar to current probes 112, 208, and 510, the current probe 710 is configured to sense a capacitively coupled current within the assembly 702, the current being caused by the formation of plasma in the plasma channel. The current probe 710 may be electrically coupled to a controller 730. The dielectric barrier layer 714 is much thicker than the dielectric coating layers 708A and 708B. Illustratively, the barrier layer 714 is 5 to 10 times thicker than the dielectric coating layers 708A and 708B. This means that any erosion of the dielectric barrier layer 714 due to plasma contact is negligible in comparison to the dielectric coating layers 708A and 708B. The current sensed by the current probe 710 therefore is only influenced by the ionized gas or combination of ionized gas species present in the plasma channel 720 (shown below in FIG. 9) and provides a reference measurement for the controller 730. In other words, the controller may use the sensed current to detect a change in composition of process gas in the plasma channel, and/or it may use the sensed current to detect a change in composition of, and thereby the stability of, plasma in the plasma channel. The current sensed by the current probe 710 through the electrode 716 is relatively stable under constant gas conditions. If a significant current change is sensed but the input gas conditions to the RPS remain the same, the change in current suggests that the plasma is not stable.

In a related embodiment, the controller 730 is coupled to both the current probe 710, coupled to the electrode 716, and a second current probe (not shown) that is inductively or electrically coupled to the housing 704 or one of the flanges 706A or 706B. In this embodiment, the controller 730 calculates the thickness of the dielectric coating by taking into account the reference measurement from the electrode. As described above, current detected by a sensor coupled to a dielectric coating layer is sensitive to the variation of coating thickness, gas flow, and/or gas composition. On the other hand, current sensed by a sensor coupled to the dielectric barrier layer is relatively stable due to the negligible variation of dielectric barrier layer thickness over time. Therefore, using both currents enables the controller 730 to calculate the thickness of the dielectric coating layer independent of the gas flow or gas composition in the plasma channel.

In addition, the controller 730 may be configured to switch the electrode 716 between electrically coupled to ground and electrically floating. Being electrically floating allows for the electrode 716 to be used for ignition purposes. Because the electrode 716 is coupled to the dielectric barrier layer 714, which is much thicker than the usually used dielectric coating layers 708A and 708B, the electrode 716 may be configured to perform as a capacitively coupled plasma source by using high ignition voltages to ignite the gases in the plasma channel without arcing through the dielectric barrier layer. This allows the electrode 716 to ignite process gases, such as nitrogen trifluoride, hydrogen, oxygen, ammonia, and/or others, directly without having to first ignite argon, which has a lower breakdown voltage. The direct ignition of process gases increases process efficiency and decreases the chances for unwanted effects caused by the initial ignition of argon, such as plasma extinguish, argon bombardment, etc.

FIG. 8 shows current sensing results obtained from an in-situ current sensing apparatus in accordance with an embodiment of the present invention. More specifically, FIG. 8 shows results obtained by coupling the current probe to the electrically conductive housing of the in-situ current sensing apparatus, such as exemplarily shown in the embodiments of FIG. 2 (directly coupled to the housing) and FIG. 5 (coupled to a flange). As can be seen, and as described above with reference to controller 230, the sensed current has a linear relationship with the thickness of the dielectric coating layer. FIG. 8 shows this relationship for three different thicknesses and three different combinations of gases. For all three combinations, argon, argon and nitrogen fluoride, and argon and hydrogen, the sensed current for a thickness of 28 micrometers is higher than the sensed current for a thickness of 40 micrometers, and the sensed current for a thickness of 40 micrometers is higher than the sensed current for a thickness of 52 micrometers. It can also be seen that the sensed current depends on the composition of the gas and/or plasma in the plasma channel.

FIG. 9 shows current sensing results obtained from an in-situ current sensing apparatus in accordance with an embodiment of the present invention. More specifically, FIG. 9 shows results obtained by coupling the current probe to an electrode embedded in the housing, such as exemplarily shown in the embodiment of FIG. 7. Because, as described above, the dielectric barrier layer is thicker than the dielectric coating layer, it erodes more slowly and is therefore relatively stable. Still, the sensed current changes based on the gases present in the plasma channel. FIG. 9 shows the sensed current for three different gases or combinations of gases: argon, argon and nitrogen fluoride, and argon and hydrogen. The sensed current is higher for argon and hydrogen than it is for argon and nitrogen fluoride, and the sensed current is higher for argon and nitrogen fluoride than it is for argon alone. Therefore, the sensed current provides an indirect measurement of the composition of gases and/or plasma in the plasma channel. By monitoring the input gas conditions over time, plasma stability can be assessed. If the sensed current stays substantially the same, the plasma is stable. A sensed current that significantly changes within a short period of time for unchanged input conditions suggests that the plasma is unstable.

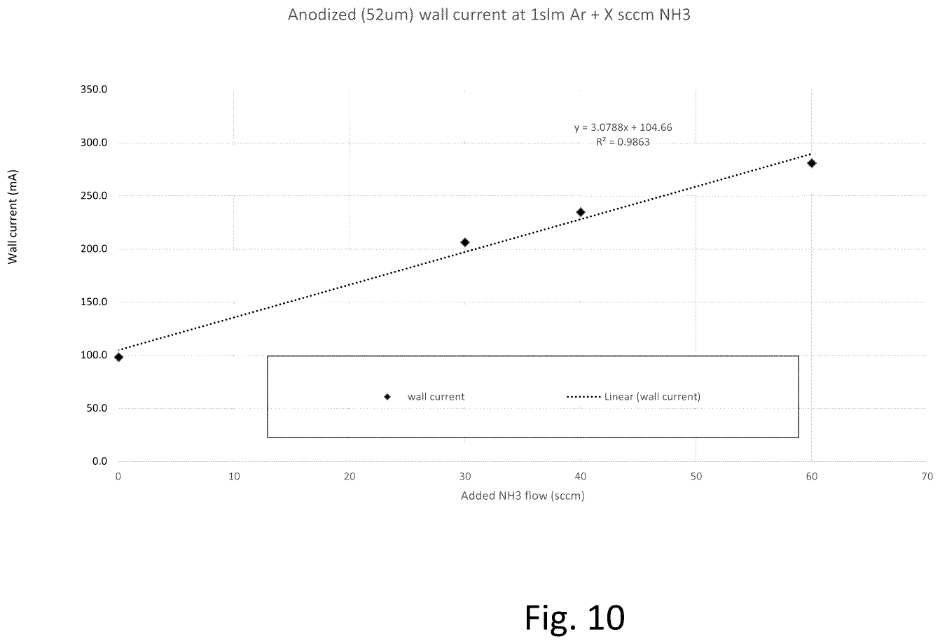

FIG. 10 shows current sensing results obtained from an in-situ current sensing apparatus in accordance with an embodiment of the present invention. More specifically, FIG. 10 shows the relationship between current sensed by a sensor inductively or electrically coupled to the housing or a flange and gas flow in the plasma chamber. It can be seen that the sensed current has a linear relationship with the gas flow. The higher the flow of ammonia in the plasma chamber is, the higher is the sensed current.

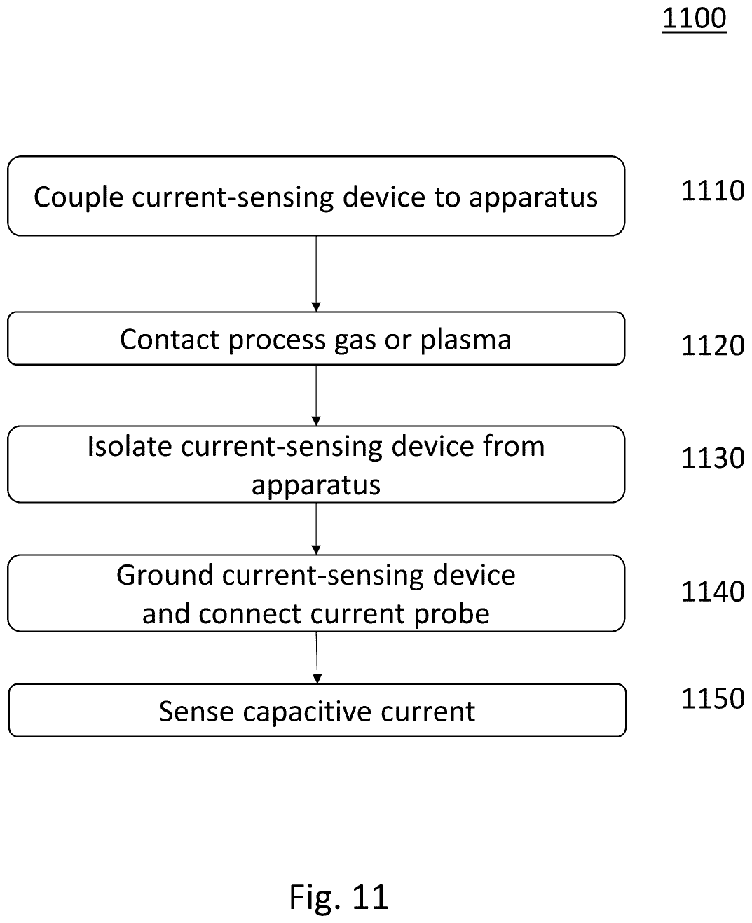

FIG. 11 is a flowchart of a method for performing in-situ current sensing in accordance with an embodiment of the present invention. Method 1100 performs in-situ current sensing in a plasma processing apparatus that has one or more sections defining a plasma channel. For example, the method 1100 may be performed to sense current in any of the plasma processing apparatus described above with reference to FIGS. 1, 3, 4, and 6. The method 1100 may also be performed to sense current in any other suitable plasma processing apparatus.

In step 1110, a current-sensing device is coupled to a plasma processing apparatus. The current-sensing device includes an assembly that includes an electrically conductive housing coupled to a dielectric coating layer. The current-sensing device also includes a current probe inductively or electrically connected to the assembly. By way of example, the current-sensing device 700 as shown and described above with reference to FIG. 7 is coupled to a plasma processing system (shown in FIG. 6). As in the system shown in FIGS. 6 and 7, the current-sensing device 700 is integrally formed with the plasma processing apparatus such that the current-sensing device is one of the one or more sections. In this example, the current-sensing device 700 is one of the mid-block sections.

As described above, the current-sensing device 700 includes an assembly 702 with an electrically conductive housing 704 coupled to a dielectric coating layer 708A. The current-sensing device 700 also includes a current probe 710 inductively or electrically connected to the assembly 702. The exemplary housing 704 includes a flange 706A defined by the housing and coupled to the dielectric coating layer 708A. The housing 704 also may have an electrode 716 that is embedded in the housing between an insulating layer 712 and a dielectric barrier layer 714. The dielectric barrier layer is adapted to contact the plasma and/or gas in the plasma channel. Also as shown and described in detail above, the current probe 710 may be electrically connected between ground and the housing 704 and/or one of the flanges 706A and 706B of the housing 704.

In step 1120, a surface of the dielectric coating layer of the current-sensing device contacts at least one of a process gas or a plasma in the plasma channel. Using the same example of FIG. 7, the dielectric coating layer 708A contacts the process gas and/or plasma 720 present in the plasma channel.

In step 1130, the current-sensing device is electrically isolated from the one or more sections of the processing apparatus. In the example of FIG. 7, the current-sensing device 700 is electrically isolated from the one or more section of the plasma processing apparatus shown in FIG. 7 by at least one dielectric break.

In step 1140, the current sensing device is electrically grounded, and the current probe is inductively or electrically connected. As described above, the current sensing device is electrically grounded to allow detecting a current. In a related embodiment, the electrode 716 may be used to ignite the plasma in the plasma channel in a plasma ignition process as described above. In that case, the electrode 716 is electrically floating during the plasma ignition process. The electrode 716 is then switched to being electrically grounded after the plasma ignition process to allow for current sensing.

In step 1150, the current probe senses a capacitive current in the assembly 702. In one embodiment, using the same example of FIG. 7, and as described in detail above, the electrode 716 is electrically connected to ground to allow for the capacitive current to flow through and to be sensed by the current probe 710.

As described in detail above, the method may include further steps to process the sensed capacitive current. These steps may be executed, for example, by controller 730. The method may include detecting erosion in a thickness of the dielectric coating layer using the sensed current. The method may also include detecting a change in the composition of the process gas using the sensed current. The method may further include detecting a degree of stability of the plasma in the plasma channel using the sensed current.

Embodiments of the present invention may be embodied in many different forms, including, but in no way limited to, computer program logic for use with a processor (e.g., a microprocessor, microcontroller, digital signal processor, or general purpose computer), programmable logic for use with a programmable logic device (e.g., a Field Programmable Gate Array (FPGA) or other PLD), discrete components, integrated circuitry (e.g., an Application Specific Integrated Circuit (ASIC)), or any other means including any combination thereof.

Computer program logic implementing all or part of the functionality previously described herein may be embodied in various forms, including, but in no way limited to, a source code form, a computer executable form, and various intermediate forms (e.g., forms generated by an assembler, compiler, networker, or locator.) Source code may include a series of computer program instructions implemented in any of various programming languages (e.g., an object code, an assembly language, or a high-level language such as Fortran, C, C++, JAVA, or HTML) for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

The computer program may be fixed in any form (e.g., source code form, computer executable form, or an intermediate form) either permanently or transitorily in a tangible storage medium, such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), a PC card (e.g., PCMCIA card), or other memory device. The computer program may be fixed in any form in a signal that is transmittable to a computer using any of various communication technologies, including, but in no way limited to, analog technologies, digital technologies, optical technologies, wireless technologies, networking technologies, and internetworking technologies. The computer program may be distributed in any form as a removable storage medium with accompanying printed or electronic documentation (e.g., shrink wrapped software or a magnetic tape), preloaded with a computer system (e.g., on system ROM or fixed disk), or distributed from a server or electronic bulletin board over the communication system (e.g., the Internet or World Wide Web).

Hardware logic (including programmable logic for use with a programmable logic device) implementing all or part of the functionality previously described herein may be designed using traditional manual methods, or may be designed, captured, simulated, or documented electronically using various tools, such as Computer Aided Design (CAD), a hardware description language (e.g., VHDL or AHDL), or a PLD programming language (e.g., PALASM, ABEL, or CUPL).

The foregoing description described certain example embodiments. It will be apparent, however, that other variations and modifications may be made to the described embodiments, with the attainment of some or all of their advantages. Accordingly, the foregoing description is to be taken only by way of example, and not to otherwise limit the scope of the disclosure. It is the object of the appended claims to cover all such variations and modifications as come within the true spirit and scope of the disclosure.

What is claimed is:

1. An in-situ current sensing apparatus for a plasma processing system comprising one or more sections defining a plasma channel, the plasma processing system configured to form a plasma in the plasma channel using a process gas, the in-situ current sensing apparatus comprising:
an assembly including an electrically conductive housing coupled to a dielectric coating layer, wherein a surface of the dielectric coating layer is configured to physically contact at least one of the process gas or the plasma in the plasma channel;
a current probe, inductively or electrically connected to the assembly, for sensing a capacitively-coupled current within the assembly caused by the formation of plasma in the plasma channel; and
at least one dielectric break for electrically isolating the assembly from the one or more sections.

2. The apparatus of claim 1, wherein the electrically conductive housing includes one or more electrically conductive flanges coupled to the dielectric coating layer.

3. The apparatus of claim 2, wherein the current probe is connected to one of the one or more flanges.

4. The apparatus of claim 2, wherein the assembly further includes an electrode embedded within the housing between an insulation layer and a dielectric barrier layer, the dielectric barrier layer adapted to contact the plasma in the plasma channel.

5. The apparatus of claim 4, wherein the current probe is inductively or electrically coupled to the electrode.

6. The apparatus of claim 1, wherein the current probe is inductively or electrically coupled to the housing.

7. The apparatus of claim 1, wherein the assembly is configured to be electrically coupled to ground for sensing the capacitively coupled current.

8. The apparatus of claim 1, wherein the assembly is configured to be switched between electrically coupled to ground and electrically floating.

9. The apparatus of claim 1, further comprising a controller electrically coupled to the current probe and configured to receive the sensed current from the current probe.

10. The apparatus of claim 9, wherein the controller is further configured to calculate a thickness of the dielectric coating layer based on the sensed current.

11. The apparatus of claim 9, wherein the controller is further configured to detect a change in composition of the process gas based on the sensed current.

12. The apparatus of claim 9, wherein the controller is further configured to determine stability of the plasma in the plasma channel.

13. The apparatus of claim 1, wherein the one or more sections of the plasma processing system include at least one input section, a plurality of mid-block sections and at least one output section, the assembly being one of the mid-block sections of the plasma processing system.

14. The apparatus of claim 13, wherein the at least one dielectric break includes:
a first dielectric break located at an interface between the one mid-block section and the at least one input section; and
a second dielectric break located at an interface between the one mid-block section and the at least one output section,
wherein the first and second dielectric breaks are configured to electrically isolate the one mid-block section from the input and output sections.

15. A method for performing in-situ current sensing in a plasma processing apparatus comprising one or more sections defining a plasma channel, the method comprising:
coupling a current-sensing device to the plasma processing apparatus, wherein the current-sensing device includes an assembly comprising an electrically conductive housing coupled to a dielectric coating layer and a current probe inductively or electrically connected to the assembly;
contacting, by a surface of the dielectric coating layer of the current-sensing device, at least one of a process gas or a plasma in the plasma channel;
electrically isolating the current-sensing device from the one or more sections of the plasma processing apparatus;
electrically grounding the current-sensing device; and
sensing, by the current probe, a capacitive current in the assembly.

16. The method of claim 15, wherein the assembly of the current-sensing device further includes (i) at least one flange defined by the housing, the at least one flange coupled to the dielectric coating layer; and (ii) an electrode embedded in the housing between an insulating layer and a dielectric barrier layer, the dielectric barrier layer adapted to contact at least one of the plasma gas or the plasma in the plasma channel.

17. The method of claim 16, further comprising using the embedded electrode to ignite the plasma in the plasma channel in a plasma ignition process, wherein the embedded electrode is electrically floating during the plasma ignition process.

18. The method of claim 17, wherein sensing the capacitive current by the current probe is performed after the plasma ignition process by electrically grounding one of the embedded electrode and the conductive housing.

19. The method of claim 18, wherein the current probe is one of inductively coupled to a grounding path and electrically connected between ground and one of the embedded electrode and the conductive housing to sense the capacitive current.

20. The method of claim 18, wherein the current probe is one of inductively coupled to a grounding path and electrically connected between ground and the at least one flange of the assembly to sense the capacitive current.

21. The method of claim 18, further comprising detecting erosion in a thickness of the dielectric coating layer using the sensed current.

22. The method of claim 18, further comprising detecting a change in composition of the process gas using the sensed current.

23. The method of claim 18, further comprising detecting a degree of stability of the plasma in the plasma channel using the sensed current.

24. The method of claim 15, wherein the current-sensing device is integrally formed with the plasma processing apparatus such that the current-sensing device is one of the one or more sections.
